(19) United States
(12) Patent Application Publication
(10) Pub. No.: US 2026/0227687 A1
(43) Pub. Date: Aug. 6, 2026

(54) MULTILAYER REFLECTIVE FILM COATED SUBSTRATE, REFLECTIVE MASK BLANK, REFLECTIVE MASK, METHOD FOR MANUFACTURING MULTILAYER REFLECTIVE FILM COATED SUBSTRATE, METHOD FOR MANUFACTURING REFLECTIVE MASK BLANK, AND METHOD FOR MANUFACTURING REFLECTIVE MASK

(71) Applicant: AGC Inc., Tokyo (JP)

(72) Inventors: Kazuma SAKATA, Koriyama-shi (JP); Naoaki MIYAMOTO, Koriyama-shi (JP)

(73) Assignee: AGC Inc., Tokyo (JP)

(21) Appl. No.: 19/634,664

(22) Filed: Mar. 31, 2026

Related U.S. Application Data
(63) Continuation of application No. PCT/JP2024/032183, filed on Sep. 9, 2024.

(30) Foreign Application Priority Data
Oct. 3, 2023 (JP) 2023-172344

(51) Int. Cl. G03F 1/24; G03F 1/84

(52) U.S. Cl. CPC G03F 1/24; G03F 1/84

(57) ABSTRACT

A multilayer reflective film coated substrate includes a substrate and a multilayer reflective film that reflects EUV light. The multilayer reflective film has, on a peripheral portion of a surface thereof on a side opposite to the substrate, three or more first reference marks to be used as reference positions when a position of a defect in the multilayer reflective film is identified. A defect having approximately the same size as each of the three or more first reference marks is not present within 100 μm from the first reference mark in the multilayer reflective film when the surface of the multilayer reflective film is viewed from a front surface.

### CROSS-REFERENCE TO RELATED APPLICATION

This application is a continuation application of International Application No. PCT/JP2024/032183, filed on Sep. 9, 2024, which claims the benefit of priority of the prior Japanese Patent Application No. 2023-172344, filed on Oct. 3, 2023 in Japan, the content of which are incorporated herein by reference.

### TECHNICAL FIELD

The present disclosure relates to a multilayer reflective film coated substrate, a reflective mask blank, a reflective mask, a method for manufacturing a multilayer reflective film coated substrate, a method for manufacturing a reflective mask blank, and a method for manufacturing a reflective mask.

### BACKGROUND ART

In recent years, with the miniaturization of semiconductor devices, EUV lithography (EUVL), which is an exposure technology using extreme ultra-violet (EUV) rays, has been developed. EUV includes soft X-rays and vacuum ultraviolet rays, and specifically refers to light with a wavelength of approximately 0.2 nm to 100 nm. At present, EUV with a wavelength of approximately 13.5 nm is mainly being considered.

In EUVL, a reflective mask is used. The reflective mask has, for example, a glass substrate, a multilayer reflective film, and an absorbing film, in that order. The multilayer reflective film reflects EUV light. The absorbing film absorbs EUV light. The absorbing film may not only absorb EUV light but also shift the phase of EUV light. That is, the absorbing film may be a phase shift film. In EUVL, an opening pattern of the absorbing film is transferred onto a target substrate such as a semiconductor substrate. Transferring includes transferring with reduction.

The position of the opening pattern in the absorbing film is determined according to, for example, the position of the defect in the multilayer reflective film. Specifically, the position where the opening pattern is formed is determined such that the defect in the multilayer reflective film is not exposed by the formation of the opening pattern in the absorbing film. This is because if the defect in the multilayer reflective film is exposed, at least one of the phase and amplitude of EUV light reflected by the multilayer reflective film will change, resulting in a decrease in the transfer accuracy of the opening pattern.

The position of the defect in the multilayer reflective film is detected by an inspection device. The inspection device identifies the position of the defect in the multilayer reflective film as a relative position to the position of a reference mark. Patent Document 1 describes the use of four or more reference marks to improve the accuracy of conversion from the coordinate system of an inspection device that detects the defect in a multilayer reflective film to the coordinate system of a device other than the inspection device.

### RELATED ART DOCUMENT

### Patent Document

Patent Document 1: PCT International Publication No. WO 2020/095959

### SUMMARY

### Problems to be Solved by the Invention

The reference marks are usually formed on the peripheral portion of the surface of the multilayer reflective film. The opening pattern of the absorbing film is not formed on the peripheral portion of the surface of the multilayer reflective film. Therefore, in the related art, the defect at the peripheral portion of the surface of the multilayer reflective film has been neglected. However, if a defect of approximately the same size as the reference mark is present in the vicinity of the reference mark, the inspection device will mistakenly recognize the defect as a reference mark. As a result, the accuracy of detecting the position of the defect decreases.

One aspect of the present disclosure provides a technology for accurately identifying the position of a defect in a multilayer reflective film.

### Means for Solving the Problem

A multilayer reflective film coated substrate according to one aspect of the present disclosure includes a substrate and a multilayer reflective film that reflects EUV light. The multilayer reflective film has, on a peripheral portion of a surface thereof on a side opposite to the substrate, three or more first reference marks to be used as reference positions when a position of a defect in the multilayer reflective film is identified. A defect having approximately the same size as each of the three or more first reference marks is not present within 100 μm from the first reference mark in the multilayer reflective film when the surface of the multilayer reflective film is viewed from a front surface.

### Advantage of the Invention

According to one aspect of the present disclosure, it is possible to accurately identify the position of a defect in a multilayer reflective film.

### BRIEF DESCRIPTION OF THE DRAWINGS

FIG. 1 A cross-sectional view showing a reflective mask blank according to one embodiment.

FIG. 2 A flowchart showing a method for manufacturing a reflective mask blank according to one embodiment.

FIG. 3 A cross-sectional view showing a reflective mask according to one embodiment.

FIG. 4 A flowchart showing a method for manufacturing a reflective mask according to one embodiment.

FIG. 5(A) being a cross-sectional view showing an example of S201, FIG. 5(B) being a cross-sectional view showing an example of S202, and FIG. 5(C) being a cross-sectional view showing an example of S203.

FIG. 6 A cross-sectional view showing an example of EUV light reflected by the reflective mask of FIG. 3.

FIG. 7 A plan view showing a multilayer reflective film coated substrate according to one embodiment.

FIG. 8 A plan view showing a multilayer reflective film coated substrate according to a reference example.

FIG. 9 A plan view showing a multilayer reflective film coated substrate according to a first modification example.

FIG. 10 A plan view showing a multilayer reflective film coated substrate according to a second modification example.

FIG. 11 A plan view showing an absorbing film formed on the multilayer reflective film coated substrate shown in FIG. 7.

FIG. 12 A side view showing an example of an ultrasonic cleaning device.

FIG. 13 A plan view showing an example of movement of a cleaning head.

FIG. 14 A plan view showing the movement range of a cleaning head according to Test Example 1.

FIG. 15 A plan view showing the movement range of a cleaning head according to Test Example 2.

### DESCRIPTION OF THE EMBODIMENTS

Hereinafter, embodiments of the present disclosure will be described with reference to the drawings. In each drawing, the same or corresponding constituent elements are designated by the same reference signs, and the description thereof may be omitted. In this specification, the use of “to” indicating a numerical range means that the numerical values described before and after “to” are included as a lower limit value and an upper limit value. The numerical range includes a range obtained by rounding off.

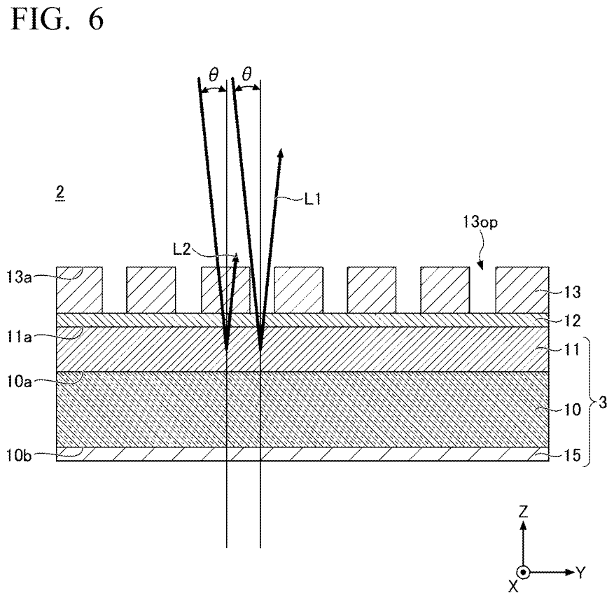

In each drawing, an X-axis direction, a Y-axis direction, and a Z-axis direction are orthogonal to each other. The Z-axis direction is a direction perpendicular to a first main surface 10a of a substrate 10. The X-axis direction is a direction orthogonal to a surface of incidence of EUV light (a surface including an incident light ray and a reflected light ray). As shown in FIG. 6, the incident light ray is inclined in a positive Y-axis direction as it travels in a negative Z-axis direction, and the reflected light ray is inclined in the positive Y-axis direction as it travels in the positive Z-axis direction.

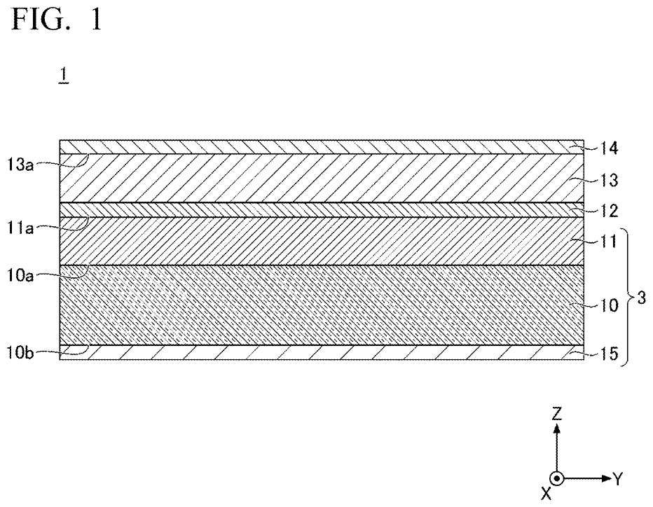

A reflective mask blank 1 according to one embodiment will be described with reference to FIG. 1. The reflective mask blank 1 has, for example, a substrate 10, a multilayer reflective film 11, a protective film 12, an absorbing film 13, and a hard mask film 14, in that order. The multilayer reflective film 11, the protective film 12, the absorbing film 13, and the hard mask film 14 are formed on the first main surface 10a of the substrate 10, in that order. The multilayer reflective film 11 reflects EUV light. The protective film 12 protects the multilayer reflective film 11 from a first etching gas during processing of the absorbing film 13. The absorbing film 13 absorbs EUV light. The absorbing film 13 may not only absorb EUV light but also shift the phase of EUV light. That is, the absorbing film 13 may be a phase shift film. The hard mask film 14 protects a part of the absorbing film 13 from the first etching gas during processing of the absorbing film 13.

The reflective mask blank 1 may have a conductive film 15 on a side of the substrate 10 opposite to the multilayer reflective film 11. That is, the reflective mask blank 1 may have the conductive film 15, the substrate 10, the multilayer reflective film 11, the protective film 12, the absorbing film 13, and the hard mask film 14, in that order. The conductive film 15 is formed on a second main surface 10b of the substrate 10. The second main surface 10b is a surface on a side opposite to the first main surface 10a. The conductive film 15 is used, for example, to adsorb a reflective mask 2 to an electrostatic chuck of an exposure device.

The reflective mask blank 1 may further have a functional film not shown in FIG. 1. For example, the reflective mask blank 1 may have a diffusion barrier film (not shown) between the multilayer reflective film 11 and the protective film 12. The diffusion barrier film prevents metal elements included in the protective film 12 from diffusing into the multilayer reflective film 11.

Although it is not shown, the reflective mask blank 1 may have a buffer film between the protective film 12 and the absorbing film 13. The buffer film protects the protective film 12 from the first etching gas for forming an opening pattern 13op in the absorbing film 13. The buffer film is etched more slowly than the absorbing film 13. Unlike the protective film 12, the buffer film will ultimately have the same opening pattern as the opening pattern 13op of the absorbing film 13.

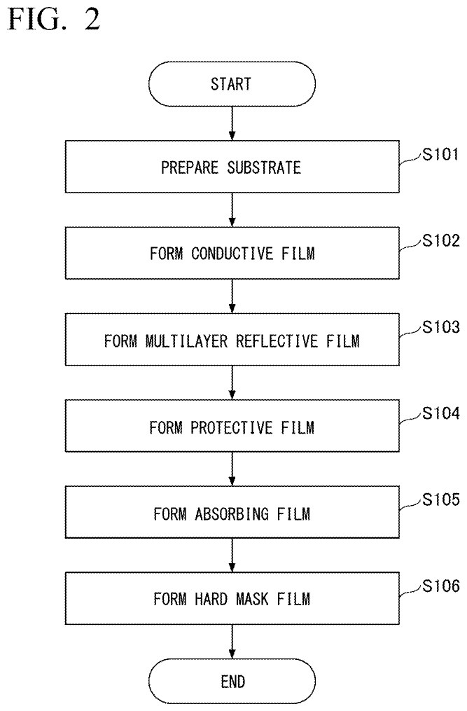

Next, a method for manufacturing the reflective mask blank 1 according to one embodiment will be described with reference to FIG. 2. The method for manufacturing the reflective mask blank 1 includes, for example, steps S101 to S106 shown in FIG. 2. In step S101, the substrate 10 is prepared. In step S102, the conductive film 15 is formed on the second main surface 10b of the substrate 10. In step S103, the multilayer reflective film 11 is formed on the first main surface 10a of the substrate 10. In step S104, the protective film 12 is formed on the multilayer reflective film 11. In step S105, the absorbing film 13 is formed on the protective film 12. In step S106, the hard mask film 14 is formed on the absorbing film 13.

The order of steps S101 to S106 is not limited to the order shown in FIG. 2. For example, the order of step S102 and steps S103 to S106 may be reversed. In addition, the method for manufacturing the reflective mask blank 1 does not necessarily have to include all of steps S101 to S106. The method for manufacturing the reflective mask blank 1 may further include a step of forming a functional film not shown in FIG. 2.

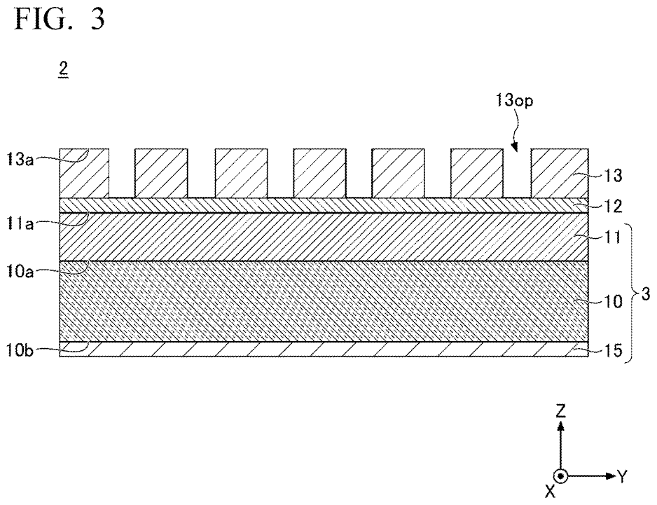

Next, the reflective mask 2 according to one embodiment will be described with reference to FIG. 3. The reflective mask 2 includes, for example, the reflective mask blank 1 shown in FIG. 1, and includes the opening pattern 13op in the absorbing film 13. In EUVL, the opening pattern 13op of the absorbing film 13 is transferred onto a target substrate such as a semiconductor substrate. Transferring includes transferring with reduction. The hard mask film 14 shown in FIG. 1 is not included in the reflective mask 2.

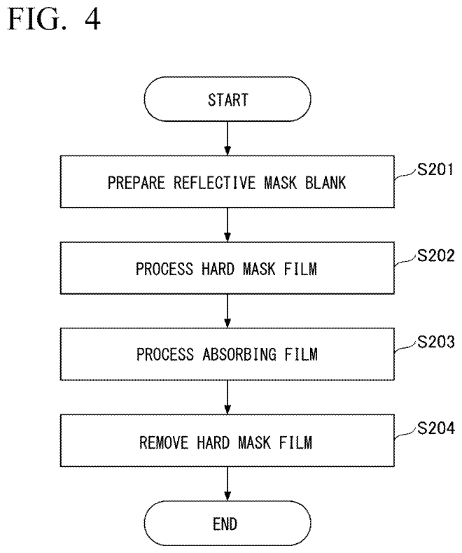

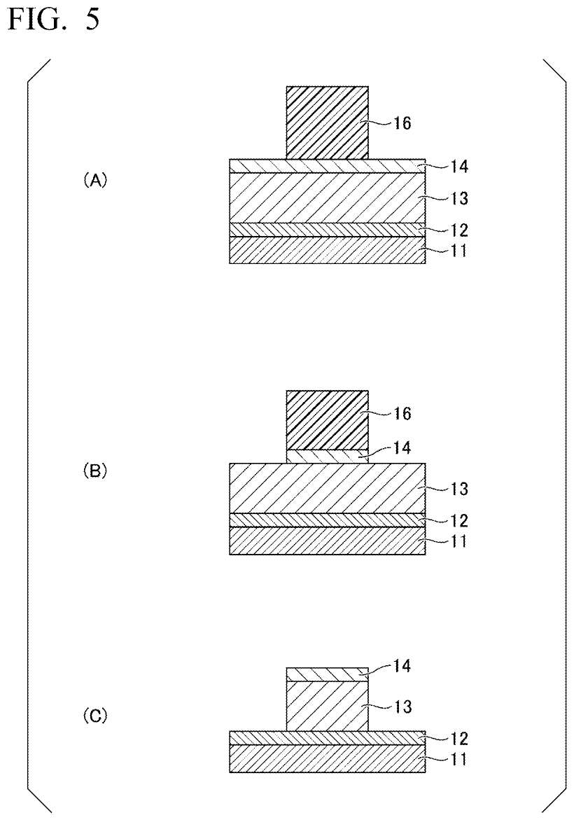

Next, a method for manufacturing the reflective mask 2 according to one embodiment will be described with reference to FIGS. 4 and 5. The method for manufacturing the reflective mask 2 includes steps S201 to S204 shown in FIG. 4. In step S201, as shown in FIG. 5(A), the reflective mask blank 1 is prepared. The reflective mask blank 1 includes a resist film 16 as shown in FIG. 5(A). The resist film 16 is formed on the hard mask film 14. The resist film 16 has an opening pattern formed therein to be transferred to the absorbing film 13.

In step S202, as shown in FIG. 5(B), the hard mask film 14 is processed using the resist film 16 having the opening pattern. At an opening of the resist film 16, the hard mask film 14 is exposed to a second etching gas, and the second etching gas etches the hard mask film 14. At the end of step S202, the resist film 16 remains. As a result, the opening pattern of the resist film 16 is transferred to the hard mask film 14.

The second etching gas is selected depending on a combination of a material of the resist film 16 and a material of the hard mask film 14, and is not particularly limited, but includes, for example, a fluorine-based gas. The fluorine-based gas includes at least one selected from, for example, CF₄ gas, CHF₃ gas, C₂F₆ gas, C₃F₆ gas, C₄F₆ gas, C₄F₈ gas, CH₂F₂ gas, CH₃F gas, C₃F₈ gas, F₂ gas, SF₆ gas, and NF₃ gas. The second etching gas may include an active gas or an inert gas in addition to the fluorine-based gas. The active gas includes at least one selected from, for example, O₂ gas and O₃ gas. The inert gas includes at least one selected from, for example, N₂ gas, He gas, and Ar gas. The second etching gas is preferably in the form of plasma.

In step S203, as shown in FIG. 5(C), the absorbing film 13 is processed using the hard mask film 14 having the opening pattern. At an opening of the hard mask film 14, the absorbing film 13 is exposed to the first etching gas, and the first etching gas etches the absorbing film 13. The hard mask film 14 has higher resistance to the first etching gas than the absorbing film 13. At the end of step S203, the hard mask film 14 remains. As a result, the opening pattern of the hard mask film 14 is transferred to the absorbing film 13.

The first etching gas is selected depending on a combination of a material of the hard mask film 14 and a material of the absorbing film 13, and is not particularly limited, but includes, for example, a chlorine-based gas and an oxygen-based gas. The chlorine-based gas includes at least one selected from, for example, Cl₂ gas, SiCl₄ gas, CHCl₃ gas, CCl₄ gas, and BCl₃ gas. The oxygen-based gas includes at least one selected from, for example, O₂ gas and O₃ gas. The first etching gas may include an inert gas in addition to the chlorine-based gas and the oxygen-based gas. The inert gas includes at least one selected from, for example, N₂ gas, He gas, and Ar gas. The first etching gas is preferably in the form of plasma.

In step S204, although it is not shown, the hard mask film 14 is removed. In order to remove the hard mask film 14, for example, a third etching gas is used. The third etching gas includes, for example, a fluorine-based gas, similar to the second etching gas. The third etching gas is preferably in the form of plasma. In order to remove the hard mask film 14, a chemical solution may be used.

Next, referring back to FIG. 1, the substrate 10, the multilayer reflective film 11, the protective film 12, the absorbing film 13, the hard mask film 14, and the conductive film 15 will be described in that order.

The substrate 10 is, for example, a glass substrate. The material of the substrate 10 is preferably quartz glass containing TiO₂. The quartz glass has a smaller coefficient of linear expansion and is less susceptible to a dimensional change due to a temperature change than the common soda-lime glass. The quartz glass may include 80% by mass to 95% by mass of SiO₂ and 4% by mass to 17% by mass of TiO₂. When the TiO₂ content is 4% by mass to 17% by mass, the coefficient of linear expansion is approximately zero at around room temperature, and there is almost no dimensional change at around room temperature. The quartz glass may contain a third component or impurities other than SiO₂ and TiO₂. The material of the substrate 10 may be crystallized glass in which a β-quartz solid solution is precipitated, silicon, a metal, or the like.

The substrate 10 has the first main surface 10a and a second main surface 10b on a side opposite to the first main surface 10a. The multilayer reflective film 11 and the like are formed on the first main surface 10a. The size of the substrate 10 in a plan view (viewed in the Z-axis direction) is, for example, 152 mm in length and 152 mm in width. Each of the length dimension and the width dimension may be 152 mm or more. The first main surface 10a and the second main surface 10b each have, for example, a square quality assurance area at the center thereof. The size of the quality assurance area is, for example, 142 mm in length and 142 mm in width. Each of the length dimension and the width dimension may be 142 mm or more. The quality assurance area of the first main surface 10a preferably has a root mean square roughness (Rq) of 0.15 nm or less and a flatness of 100 nm or less. In addition, it is preferable that the quality assurance area of the first main surface 10a does not have any defects that cause a phase defect.

The multilayer reflective film 11 reflects EUV light. The multilayer reflective film 11 is, for example, a film obtained by stacking high refractive index layers and low refractive index layers alternately. The material of the high refractive index layer is, for example, silicon (Si), and the material of the low refractive index layer is, for example, molybdenum (Mo), and thus a Mo/Si multilayer reflective film is used. In addition, a Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film, a Si/Ru/Mo/Ru multilayer reflective film, a Si/Ru/Mo multilayer reflective film, or the like can also be used as the multilayer reflective film 11.

The film thickness of each layer constituting the multilayer reflective film 11 and the number of repeating units of each layer can be appropriately selected depending on the material of each layer and the reflectance for EUV light. In a case in which the multilayer reflective film 11 is a Mo/Si multilayer reflective film, in order to achieve a reflectance of 60% or more with respect to EUV light having an incidence angle θ (see FIG. 6) of 6°, a Mo layer having a film thickness of 2.3±0.1 nm and a Si layer having a film thickness of 4.5±0.1 nm may be stacked so that the number of repeating units is 30 or more and 60 or less. The multilayer reflective film 11 preferably has a reflectance of 60% or more with respect to EUV light having an incidence angle θ of 6°. The reflectance is more preferably 65% or more.

A film formation method for each layer constituting the multilayer reflective film 11 is, for example, a DC sputtering method, a magnetron sputtering method, an ion beam sputtering method, or the like. In a case in which the Mo/Si multilayer reflective film is formed using an ion beam sputtering method, an example of film formation conditions for each of the Mo layer and the Si layer is as follows.

### <Film Formation Conditions for Si Layer>

Target: Si target
Sputtering gas: Ar gas
Gas pressure: 1.3×10⁻² Pa to 2.7×10⁻² Pa
Ion acceleration voltage: 300 V to 1500 V
Film formation rate: 0.030 nm/sec to 0.300 nm/sec
Film thickness of Si layer: 4.5±0.1 nm

### <Film Formation Conditions for Mo Layer>

Target: Mo target
Sputtering gas: Ar gas
Gas pressure: 1.3×10⁻² Pa to 2.7×10⁻² Pa
Ion acceleration voltage: 300 V to 1500 V
Film formation rate: 0.030 nm/sec to 0.300 nm/sec
Film thickness of Mo layer: 2.3±0.1 nm

### <Repeating Unit of Si Layer and Mo Layer>

The number of repeating units: 30 to 60 (preferably 40 to 50)

The protective film 12 is formed between the multilayer reflective film 11 and the absorbing film 13 to protect the multilayer reflective film 11. The protective film 12 protects the multilayer reflective film 11 from the first etching gas during processing of the absorbing film 13, that is, in step S203. The protective film 12 is not removed even when exposed to the first etching gas, and remains on the multilayer reflective film 11.

The protective film 12 contains at least one element selected from, for example, Ru, Rh, and Si. In a case in which the protective film 12 contains Rh, it may contain only Rh, or it may contain an Rh compound. The Rh compound may contain, in addition to Rh, at least one element selected from the group consisting of Ru, Nb, Mo, Ta, Ir, Pd, Zr, Y, and Ti.

The Rh compound may contain, in addition to Rh, at least one element selected from the group consisting of N, O, C, and B. These elements reduce the resistance of the protective film 12 to the first etching gas, but reduce the crystallinity of the protective film 12, thereby improving the smoothness of the protective film 12. When the Rh compound has an amorphous structure or a microcrystalline structure, the X-ray diffraction profile of the Rh compound does not have a clear peak.

In the present embodiment, the protective film 12 is a film made of a single layer, but it may be a multilayer film having a lower layer and an upper layer. The lower layer of the protective film 12 is a layer formed in contact with the uppermost surface of the multilayer reflective film 11. The upper layer of the protective film 12 is in contact with the lowermost surface of the absorbing film 13. In this manner, by forming the protective film 12 as a multilayer structure, a material having an excellent predetermined function can be used for each layer, and therefore the protective film 12 as a whole can be made multifunctional.

The upper layer of the protective film 12 preferably includes at least one element selected from Ru and Rh, more preferably includes Rh, and even more preferably includes an Rh compound. The lower layer of the protective film 12 preferably includes at least one element selected from Ru, Rh, Nb, Mo, Zr, Y, and Si, and more preferably includes Ru. In addition, the lower layer of the protective film 12 preferably includes, in addition to the at least one element described above, at least one element selected from C, N, and B in order to suppress the crystallinity of the protective film 12. In a case in which the protective film 12 is a multilayer film, the thickness of the protective film 12, which will be described below, means the total film thickness of the multilayer film. A mixed layer formed by mixing the components included in the multilayer reflective film 11 and the components included in the lower layer of the protective film 12 may be formed between the multilayer reflective film 11 and the lower layer of the protective film 12.

The thickness of the protective film 12 is preferably 1.0 nm to 4.0 nm, more preferably 2.0 nm to 3.5 nm, and even more preferably 2.5 nm to 3.0 nm. If the thickness of the protective film 12 is 1.0 nm or more, the etching resistance is good. In addition, if the thickness of the protective film 12 is 4.0 nm or less, the reflectance for EUV light is good.

The density of the protective film 12 is preferably 10.0 g/cm³ to 14.0 g/cm³. If the density of the protective film 12 is 10.0 g/cm³ or more, the etching resistance is good. In addition, if the density of the protective film 12 is 14.0 g/cm³ or less, the decrease in reflectance for EUV light can be suppressed.

A film formation method for the protective film 12 is, for example, a DC sputtering method, a magnetron sputtering method, an ion beam sputtering method, or the like. In a case in which an Rh film is formed using a DC sputtering method, an example of the film formation conditions is as follows.

### <Film Formation Conditions for Rh Film>

Target: Rh target
Sputtering gas: Ar gas
Gas pressure: 1.0×10⁻² Pa to 1.0×10⁰ Pa
Power density of target: 1.0 W/cm² to 8.5 W/cm²
Film formation rate: 0.020 nm/sec to 1.000 nm/sec
Film thickness: 1 nm to 10 nm

The absorbing film 13 absorbs EUV light. The absorbing film 13 is a film in which the opening pattern 13op is to be formed. The opening pattern 13op is not formed in the manufacturing process of the reflective mask blank 1, but is formed in the manufacturing process of the reflective mask 2. The absorbing film 13 may not only absorb EUV light but also shift the phase of EUV light. That is, the absorbing film 13 may be a phase shift film. The phase shift film shifts the phase of second EUV light L2 relative to first EUV light L1 shown in FIG. 6.

The first EUV light L1 is light that passes through the opening pattern 13op of the absorbing film 13 without being absorbed by the absorbing film 13, is reflected by the multilayer reflective film 11, and passes through the opening pattern 13op of the absorbing film 13 without being absorbed by the absorbing film 13 again. The second EUV light L2 is light that is transmitted through the absorbing film 13 while being absorbed by the absorbing film 13, is reflected by the multilayer reflective film 11, and is transmitted through the absorbing film 13 while being absorbed by the absorbing film 13 again.

A phase difference (≥0) between the first EUV light L1 and the second EUV light L2 is, for example, 1700 to 250°. The phase of the first EUV light L1 may be advanced or delayed relative to the phase of the second EUV light L2. The absorbing film 13 utilizes interference between the first EUV light L1 and the second EUV light L2 to improve the contrast of a transferred image. The transferred image is an image obtained by transferring the opening pattern 13op of the absorbing film 13 onto the target substrate.

In EUVL, a so-called shadowing effect occurs. The shadowing effect refers to the occurrence of an area near a side wall of the opening pattern 13op where the side wall blocks EUV light due to the incidence angle θ of EUV light being not 0° (for example, 6°), resulting in a positional deviation or a dimensional deviation of the transferred image. In order to reduce the shadowing effect, it is effective to lower the height of the side wall of the opening pattern 13op, and it is also effective to make the absorbing film 13 thinner.

The film thickness of the absorbing film 13 is, for example, 60 nm or less, and preferably 50 nm or less, in order to reduce the shadowing effect. The film thickness of the absorbing film 13 is preferably 20 nm or more, and more preferably 30 nm or more, in order to ensure a phase difference between the first EUV light L1 and the second EUV light L2.

In order to decrease the film thickness of the absorbing film 13 for reducing the shadowing effect while ensuring the phase difference between the first EUV light L1 and the second EUV light L2, it is effective to decrease the refractive index n of the absorbing film 13. In addition, in order to decrease the reflectance for EUV light, it is effective to increase the extinction coefficient k of the absorbing film 13. In this manner, the absorbing film 13 is required to have excellent optical properties.

The absorbing film 13 preferably includes at least one metal element selected from Cr, Ta, Nb, Ir, Pt, Pd, Ni, Co, Cu, Sn, Au, and Ru. These metal elements have a relatively small refractive index, and therefore it is possible to decrease the film thickness of the absorbing film 13 while ensuring a phase difference. The absorbing film 13 preferably includes a compound of the metal element. The compound of the metal element preferably includes at least one element selected from O, B, C, and N. By adding at least one element selected from O, B, C, and N, it is possible to suppress crystallization while suppressing deterioration of the optical properties, and to decrease the roughness of the opening pattern 13op.

In the present embodiment, the absorbing film 13 is a film made of a single layer, but it may be a multilayer film having a lower layer and an upper layer. The lower layer and the upper layer that constitute the absorbing film 13 are formed on the protective film 12, in that order. The uppermost layer of the absorbing film 13 is a layer farthest from the protective film 12. The uppermost layer of the absorbing film 13 preferably includes at least one metal element selected from Cr, Ta, Nb, Ir, Pt, Pd, Au, and Ru, and more preferably includes a compound of the metal element. In a case in which the absorbing film 13 is a multilayer film, the thickness of the absorbing film 13 means the total film thickness of the multilayer film.

A film formation method for the absorbing film 13 is, for example, a DC sputtering method, a magnetron sputtering method, an ion beam sputtering method, or the like. The content of nitrogen in the absorbing film 13 can be controlled by adjusting the content of N₂ gas in the sputtering gas.

In a case in which a TaN film is formed using a reactive sputtering method, an example of the film formation conditions is as follows.

### <Film Formation Conditions for TaN Film>

Target: Ta target
Power density of Ta target: 1.0 W/cm² to 8.5 W/cm²
Sputtering gas: mixed gas of Ar gas and N₂ gas
Volume ratio of N₂ gas in sputtering gas (N₂/(Ar+N₂)): 0.01 to 0.25
Gas pressure: 1.0×10⁻² Pa to 1.0×10⁰ Pa
Power density of Ta target: 1.0 W/cm² to 8.5 W/cm²
Film formation rate: 0.020 nm/sec to 0.060 nm/sec
Film thickness: 20 nm to 60 nm

The hard mask film 14 is formed on a side of the absorbing film 13 opposite to the protective film 12 and is used to form the opening pattern 13op in the absorbing film 13. The hard mask film 14 enables the resist film 16 to be made thinner.

The hard mask film 14 preferably includes at least one metal element or semi-metal element selected from Al, Hf, Y, Cr, Nb, Ti, Mo, Ru, Ta, and Si. The hard mask film 14 preferably includes a compound of the above-described metal element or semi-metal element. The compound thereof preferably includes at least one element selected from O, N, C, and B.

The film thickness of the hard mask film 14 is preferably 2 nm or more and 30 nm or less, more preferably 2 nm or more and 25 nm or less, and even more preferably 2 nm or more and 10 nm or less.

A film formation method for the hard mask film 14 is, for example, a DC sputtering method, a magnetron sputtering method, an ion beam sputtering method, or the like.

The conductive film 15 is formed on a side of the substrate 10 opposite to the multilayer reflective film 11 and is used to adsorb the reflective mask 2 to an electrostatic chuck of an exposure device. The conductive film 15 preferably includes at least one metal element selected from Cr and Ta. The conductive film 15 preferably includes a compound of the above-described metal element. The compound thereof preferably includes at least one element selected from O, N, C, and B.

In the present embodiment, the conductive film 15 is a film made of a single layer, but it may be a multilayer film having a lower layer and an upper layer. The lower layer and the upper layer that constitute the conductive film 15 are formed on the substrate 10, in that order. The uppermost layer of the conductive film 15 is a layer farthest from the substrate 10. The uppermost layer of the conductive film 15 preferably includes at least one metal element selected from Cr and Ta, and more preferably includes a compound of the above-described metal element. In a case in which the conductive film 15 is a multilayer film, the thickness of the conductive film 15 means the total film thickness of the multilayer film.

The film thickness of the conductive film 15 is preferably 5 nm or more and 500 nm or less, more preferably 10 nm or more and 450 nm or less, and even more preferably 20 nm or more and 400 nm or less.

A film formation method for the conductive film 15 is, for example, a DC sputtering method, a magnetron sputtering method, an ion beam sputtering method, or the like.

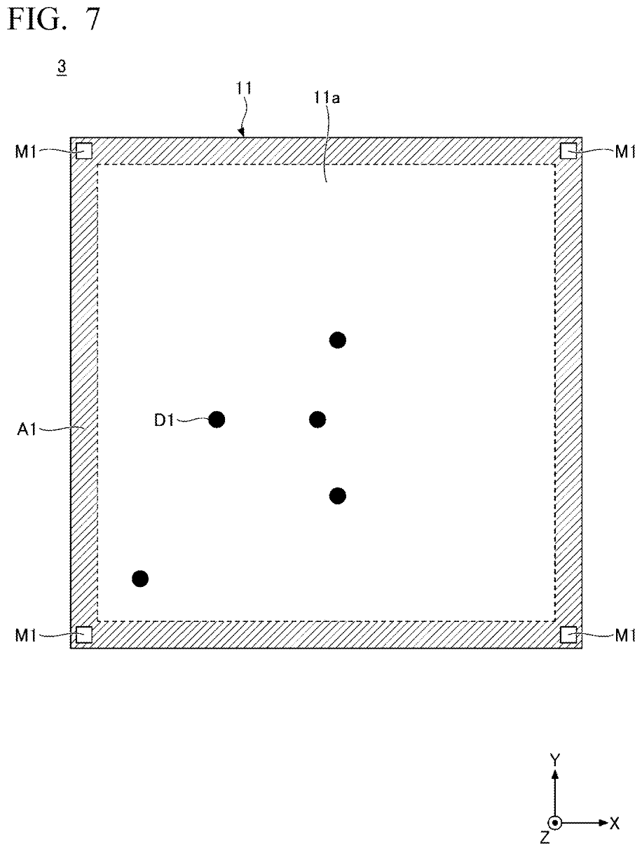

As shown in FIG. 1, a multilayer reflective film coated substrate 3 has at least the substrate 10 and the multilayer reflective film 11. The multilayer reflective film coated substrate 3 may further include the conductive film 15 as shown in FIG. 1, but may not necessarily include the conductive film 15. The multilayer reflective film 11 has three or more first reference marks M1 (see FIG. 7) on the peripheral portion of a surface 11a thereof on a side opposite to the substrate 10.

Each of the first reference marks M1 is formed, for example, in a concave shape on the surface 11a of the multilayer reflective film 11, but may also be formed in a convex shape. The first reference mark M1 is used as a reference position when the position of a defect D1 in the multilayer reflective film 11 is identified. The position of the defect D1 is identified as a relative position with respect to the first reference mark M1.

The inspection of the multilayer reflective film 11 for the defect D1 is performed immediately after the formation of the multilayer reflective film 11 (step S103). That is, the inspection of the multilayer reflective film 11 for the defect D1 is performed before another film is formed on the surface 11a of the multilayer reflective film 11. For example, the inspection of the multilayer reflective film 11 for the defect D1 is performed before the formation of the absorbing film 13 (step S105). In a case in which the formation of the multilayer reflective film 11 (step S103) and the formation of the protective film 12 (step S104) are performed consecutively using the same film forming apparatus, the inspection of the multilayer reflective film 11 for the defect D1 may be performed after the formation of the protective film 12 (step S104).

The inspection device captures an image of each of the first reference marks M1 and detects the position of each of the first reference marks M1 by performing image processing of the captured image. The inspection device sets a coordinate system on the surface 11a of the multilayer reflective film 11 on the basis of the position of each of the detected first reference marks M1. In addition, the inspection device also detects the position of each defect D1 in the set coordinate system.

If the number of first reference marks M1 is three or more, the reproducibility of the coordinate system set by the inspection device is high, and the reproducibility of the position of the defect D1 detected by the inspection device is high. The detection error of the position of the defect D1 is expressed as 3σ. σ is a standard deviation. The smaller 3σ, the higher the reproducibility. 3σ is preferably 0 nm to 20 nm or less, and more preferably 0 nm to 10 nm. 3σ is measured by the measurement method described in Patent Document 1.

The greater the number of first reference marks M1, the higher the reproducibility of the coordinate system set by the inspection device. Therefore, the number of first reference marks M1 is preferably four or more, and more preferably eight or more. However, if the number of first reference marks M1 is too large, it will take time and cost to create the first reference marks M1. Therefore, the number of first reference marks M1 is preferably 30 or less, and more preferably 20 or less.

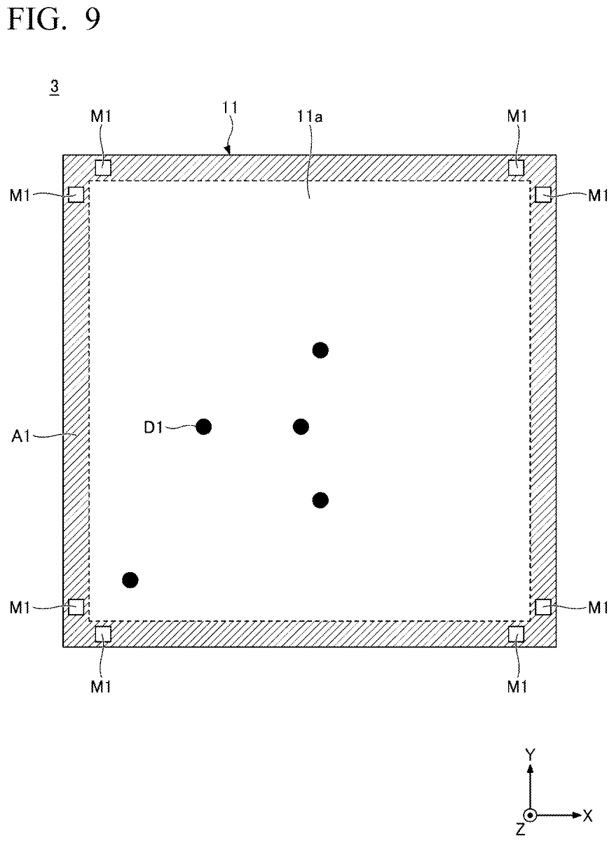

The first reference marks M1 may be formed one at each of the four corners of the surface 11a of the multilayer reflective film 11 as shown in FIG. 7, or may be formed two at each of the four corners of the surface 11a of the multilayer reflective film 11 as shown in FIG. 9. The first reference marks M1 only have to be formed on the peripheral portion of the surface 11a of the multilayer reflective film 11.

In the present specification, the peripheral portion of the surface 11a of the multilayer reflective film 11 refers to, for example, an area A1 (see FIG. 7) within 10 mm from the periphery of the first main surface 10a of the substrate 10 when the surface 11a of the multilayer reflective film 11 is viewed from the front surface. Whether the multilayer reflective film 11 is formed on the entire first main surface 10a or the multilayer reflective film 11 is formed on only a part of the first main surface 10a, A1 is an area within 10 mm from the periphery of the first main surface 10a.

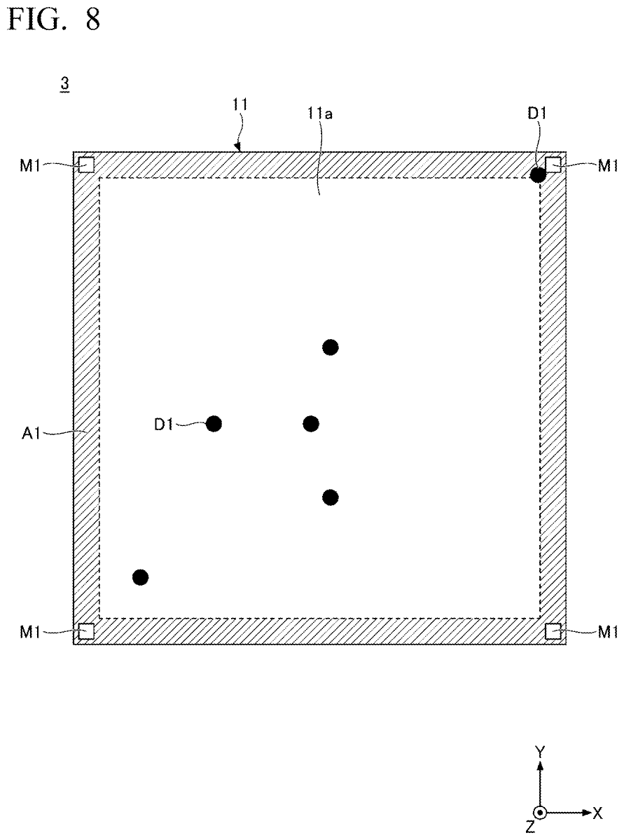

In the region A1, the opening pattern 13op of the absorbing film 13 is not formed. Therefore, in the related art, the defect D1 present in the area A1 has been neglected. However, as shown in FIG. 8, if the defect D1 having approximately the same size as the first reference mark M1 is present in the vicinity of the first reference mark M1, the inspection device may mistakenly recognize the defect D1 as the first reference mark M1. Therefore, in the related art, the reproducibility of the coordinate system set by the inspection device may be low, and the reproducibility of the position of the defect D1 detected by the inspection device may be low.

According to the present embodiment, as shown in FIG. 7, the defect D1 having approximately the same size as the first reference mark M1 is not present within 100 μm from each of the three or more first reference marks M1 in the multilayer reflective film 11 when the surface 11a of the multilayer reflective film 11 is viewed from the front surface. As a result, the image of the first reference mark M1 captured by the inspection device does not include the defect D1 having approximately the same size as the first reference mark M1. Therefore, the inspection device will not mistakenly recognize the defect D1 as the first reference mark M1. Therefore, the reproducibility of the coordinate system set by the inspection device is high, and the reproducibility of the position of the defect D1 detected by the inspection device is high.

The defect D1 having approximately the same size as the first reference mark M1 does not have to be present within 100 μm from each of the three or more first reference marks M1, and may be present within 100 μm from some of the first reference marks M1. However, it is preferable that the defect D1 having approximately the same size as the first reference mark M1 be not present within 100 μm from any of all the first reference marks M1.

In addition, the defect D1 having approximately the same size as the first reference mark M1 does not have to be present within 100 μm from the first reference mark M1, and may be present at a position beyond 100 μm from the first reference mark M1, when the surface 11a of the multilayer reflective film 11 is viewed from the front surface. This is because a position beyond 100 μm from the first reference mark M1 is not captured in an image when the inspection device captures an image of the first reference mark M1.

Furthermore, the defect D1 having a significantly larger size than the first reference mark M1 and the defect D1 having a significantly smaller size than the first reference mark M1 may be present within 100 μm from the first reference mark M1 when the surface 11a of the multilayer reflective film 11 is viewed from the front surface. This is because the inspection device will not mistakenly recognize the defect D1, which is clearly different in size, as the first reference mark M1.

From the viewpoint of preventing the inspection device from mistakenly recognizing the defect as the reference mark, it is preferable that the defect D1 having approximately the same size as the first reference mark M1 be not present within 100 μm from the first reference mark M1 in the multilayer reflective film 11, it is more preferable that the defect D1 having approximately the same size as the first reference mark M1 is not present within 500 μm from the first reference mark M1 in the multilayer reflective film 11, and it is particularly preferable that the defect D1 having approximately the same size as the first reference mark M1 is not present within 1000 μm from the first reference mark M1 in the multilayer reflective film 11.

The size of the first reference mark M1 is expressed as a circle equivalent diameter of the first reference mark M1. The circle equivalent diameter is a diameter of a perfect circle having an area equivalent to the area of a figure. In addition, the size of the defect D1 is expressed as a circle equivalent diameter of the defect D1. The circle equivalent diameter of the defect D1 having approximately the same size as the first reference mark M1 is 80% to 120% of the circle equivalent diameter of the first reference mark M1. It is sufficient that such a defect is not present within 100 μm from each of the three or more first reference marks M1.

From the viewpoint of preventing the inspection device from mistakenly recognizing the defect as the reference mark, the circle equivalent diameter of the defect D1 having approximately the same size as the first reference mark M1, is preferably 80% to 120%, more preferably 70% to 130%, even more preferably 60% to 140%, and particularly preferably 50% to 150% of the circle equivalent diameter of the first reference mark M1.

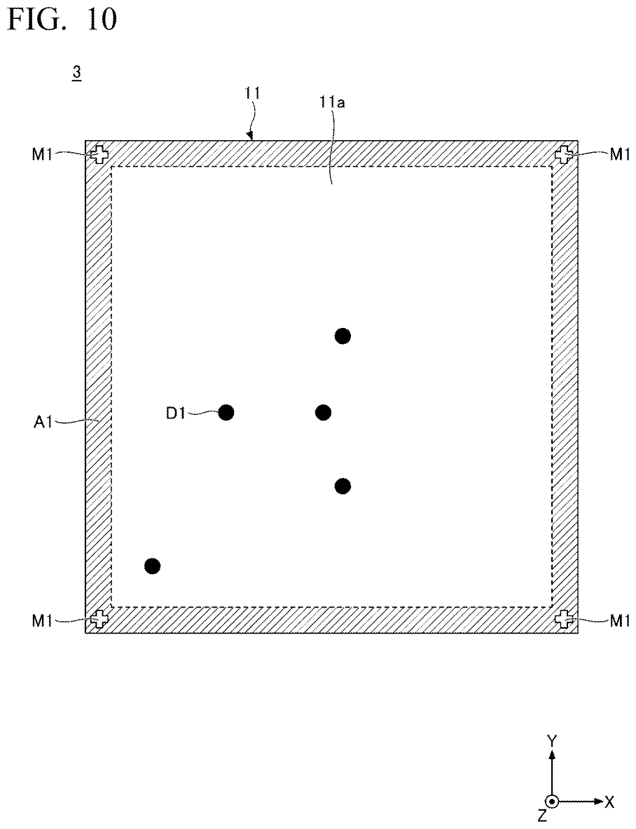

As shown in FIG. 7, each of the three or more first reference marks M1 is, for example, rectangular when the surface 11a of the multilayer reflective film 11 is viewed from the front surface. Although the first reference mark M1 shown in FIG. 7 is a square, it may be a rectangle other than a square. In addition, the shape of the first reference mark M1 is not limited to a rectangle, but may be a polygon, such as a triangle, a pentagon, or a hexagon. Furthermore, the shape of the first reference mark M1 may be, for example, a cross shape formed by two intersecting straight lines, as shown in FIG. 10.

As shown in FIG. 7, in a case in which the first reference mark M1 is rectangular when the surface 11a of the multilayer reflective film 11 is viewed from the front surface, the size of the first reference mark M1 can also be expressed as the average value of the lengths of the respective sides of the rectangle. In this case, the defect D1 having approximately the same size as the first reference mark M1 is a defect having a circle equivalent diameter that is 90% to 135% of the average value of the lengths of the respective sides of the rectangle. It is sufficient that such a defect is not present within 100 μm from each of the three or more first reference marks M1.

In a case in which the first reference mark M1 is rectangular, from the viewpoint of preventing the inspection device from mistakenly recognizing the defect as the first reference mark M1, the circle equivalent diameter of the defect D1 having approximately the same size as the first reference mark M1, is preferably 90% to 135%, more preferably 79% to 147%, even more preferably 68% to 158%, and particularly preferably 56% to 169% of the average value of the lengths of the respective sides of the rectangle.

90% to 135% of the length of one side of the square is equal to 80% to 120% of the circle equivalent diameter of the square. In addition, 79% to 147% of the length of one side of the square is equal to 70% to 130% of the circle equivalent diameter of the square. Furthermore, 68% to 158% of the length of one side of the square is equal to 60% to 140% of the circle equivalent diameter of the square. In addition, 56% to 169% of the length of one side of the square is equal to 50% to 150% of the circle equivalent diameter of the square.

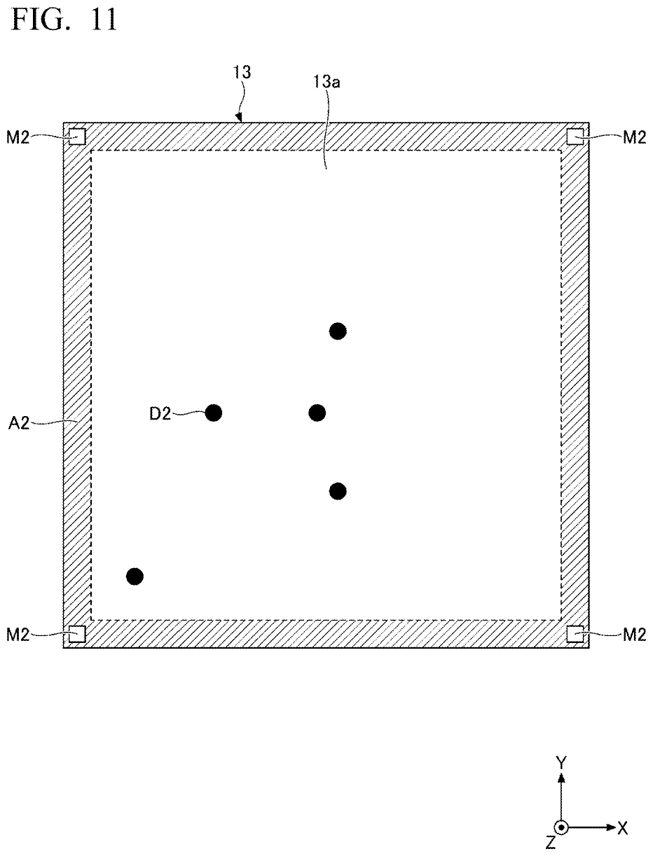

Next, an example of the absorbing film 13 formed on the multilayer reflective film coated substrate 3 shown in FIG. 7 will be described mainly with reference to FIG. 11. As shown in FIG. 11, the absorbing film 13 has three or more second reference marks M2 on the peripheral portion of a surface 13a thereof on a side opposite to the multilayer reflective film 11. Each of the second reference marks M2 is transferred from the first reference mark M1 and is formed at the same position as the first reference mark M1. The second reference mark M2 is used as a reference position when the position of a defect D2 in the absorbing film 13 is identified. The position of the defect D2 is identified as a relative position with respect to the second reference mark M2.

The inspection device captures an image of each of the second reference marks M2 and detects the position of each of the second reference marks M2 by performing image processing of the captured image. The inspection device sets a coordinate system on the surface 13a of the absorbing film 13 on the basis of the position of each of the detected second reference mark M2. In addition, the inspection device also detects the position of each defect D2 in the set coordinate system.

If the number of second reference marks M2 is three or more, the reproducibility of the coordinate system set by the inspection device is high, and the reproducibility of the position of the defect D2 detected by the inspection device is high. The detection error of the position of the defect D2 is expressed as 3σ. σ is a standard deviation. The smaller 3σ, the higher the reproducibility. 3σ is preferably 0 nm to 20 nm or less, and more preferably 0 nm to 10 nm.

The greater the number of second reference marks M2, the higher the reproducibility of the coordinate system set by the inspection device. Therefore, the number of second reference marks M2 is preferably four or more, and more preferably eight or more. However, if the number of second reference marks M2 is too large, it will take time and cost to create the second reference marks M2. Therefore, the number of second reference marks M2 is preferably 30 or less, and more preferably 20 or less.

The second reference marks M2 may be formed one at each of the four corners of the surface 13a of the absorbing film 13 as shown in FIG. 11, or may be formed two at each of the four corners of the surface 13a of the absorbing film 13, although it is not shown. The second reference marks M2 only have to be formed on the peripheral portion of the surface 13a of the absorbing film 13.

In the present specification, the peripheral portion of the surface 13a of the absorbing film 13 refers to, for example, an area A2 within 10 mm from the periphery of the first main surface 10a of the substrate 10 when the surface 13a of the absorbing film 13 is viewed from the front surface. Whether the absorbing film 13 is formed on the entire first main surface 10a or the absorbing film 13 is formed on only a part of the first main surface 10a, A2 is an area within 10 mm from the periphery of the first main surface 10a. In the region A2, the opening pattern 13op of the absorbing film 13 is not formed.

According to the present embodiment, as shown in FIG. 11, the defect D2 having approximately the same size as the second reference mark M2 is not present within 100 μm from each of the three or more second reference marks M2 in the absorbing film 13 when the surface 13a of the absorbing film 13 is viewed from the front surface. As a result, the image of the second reference mark M2 captured by the inspection device does not include the defect D2 having approximately the same size as the second reference mark M2. Therefore, the inspection device will not mistakenly recognize the defect D2 as the second reference mark M2. Therefore, the reproducibility of the coordinate system set by the inspection device is high, and the reproducibility of the position of the defect D2 detected by the inspection device is high.

The defect D2 having approximately the same size as the second reference mark M2 does not have to be present within 100 μm from each of the three or more second reference marks M2, and may be present within 100 μm from some of the second reference marks M2. However, it is preferable that the defect D2 having approximately the same size as the second reference mark M2 be not present within 100 μm from any of all the second reference marks M2.

In addition, the defect D2 having approximately the same size as the second reference mark M2 does not have to be present within 100 μm from the second reference mark M2, and may be present at a position beyond 100 μm from the second reference mark M2, when the surface 13a of the absorbing film 13 is viewed from the front surface. This is because a position beyond 100 μm from the second reference mark M2 is not captured in an image when the inspection device captures an image of the second reference mark M2.

Furthermore, the defect D2 having a significantly larger size than the second reference mark M2 and the defect D2 having a significantly smaller size than the second reference mark M2 may be present within 100 μm from the second reference mark M2 when the surface 13a of the absorbing film 13 is viewed from the front surface. This is because the inspection device will not mistakenly recognize the defect D2, which is clearly different in size, as the second reference mark M2.

From the viewpoint of preventing the inspection device from mistakenly recognizing the defect as the reference mark, it is preferable that the defect D2 having approximately the same size as the second reference mark M2 is not present within 100 μm from the second reference mark M2 in the absorbing film 13, it is more preferable that the defect D2 having approximately the same size as the second reference mark M2 is not present within 500 μm from the second reference mark M2 in the absorbing film 13, and it is particularly preferable that the defect D2 having approximately the same size as the second reference mark M2 is not present within 1000 μm from the second reference mark M2 in the absorbing film 13.

The size of the second reference mark M2 is expressed as a circle equivalent diameter of the second reference mark M2. In addition, the size of the defect D2 is expressed as a circle equivalent diameter of the defect D2. The circle equivalent diameter of the defect D2 having approximately the same size as the second reference mark M2 is 80% to 120% of the circle equivalent diameter of the second reference mark M2. It is sufficient that such a defect is not present within 100 μm from each of the three or more second reference marks M2.

From the viewpoint of preventing the inspection device from mistakenly recognizing the defect as the reference mark, the circle equivalent diameter of the defect D2 having approximately the same size as the second reference mark M2, is preferably 80% to 120%, more preferably 70% to 130%, even more preferably 60% to 140%, and particularly preferably 50% to 150% of the circle equivalent diameter of the second reference mark M2.

As shown in FIG. 11, each of the three or more second reference marks M2 is, for example, rectangular when the surface 13a of the absorbing film 13 is viewed from the front surface. Although the second reference mark M2 shown in FIG. 11 is a square, it may be a rectangle other than a square. In addition, the shape of the second reference mark M2 is not limited to a rectangle, but may be a polygon, such as a triangle, a pentagon, or a hexagon. Furthermore, the shape of the second reference mark M2 may be, for example, a cross shape formed by two intersecting straight lines.

As shown in FIG. 11, in a case in which the second reference mark M2 is rectangular when the surface 13a of the absorbing film 13 is viewed from the front surface, the size of the second reference mark M2 can also be expressed as the average value of the lengths of the respective sides of the rectangle. In this case, the defect D2 having approximately the same size as the second reference mark M2 is a defect having a circle equivalent diameter that is 90% to 135% of the average value of the lengths of the respective sides of the rectangle. It is sufficient that such a defect is not present within 100 μm from each of the three or more second reference mark M2.

In a case in which the second reference mark M2 is rectangular, from the viewpoint of preventing the inspection device from mistakenly recognizing the defect as the second reference mark M2, the circle equivalent diameter of the defect D2 having approximately the same size as the second reference mark M2, is preferably 90% to 135%, more preferably 79% to 147%, even more preferably 68% to 158%, and particularly preferably 56% to 169% of the average value of the lengths of the respective sides of the rectangle.

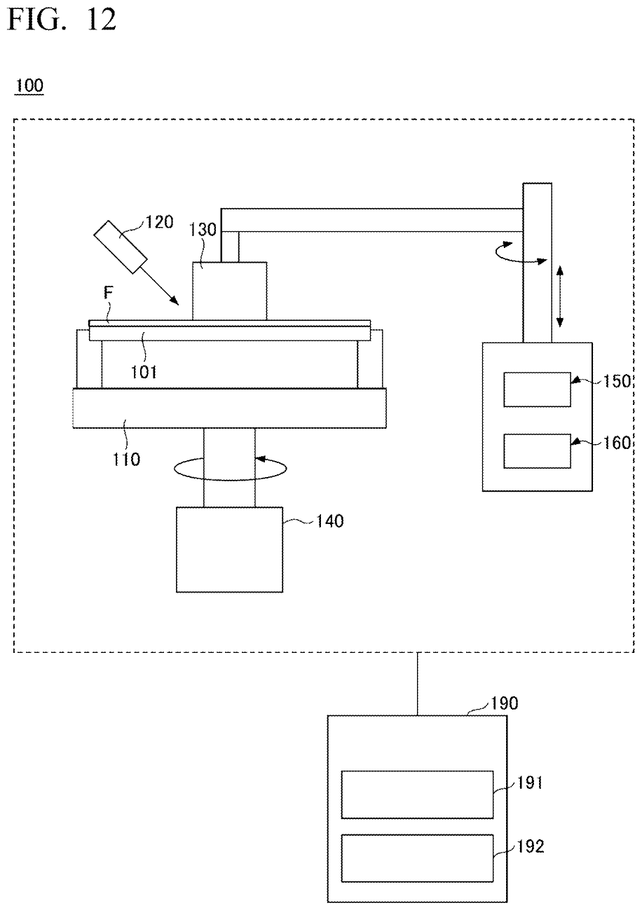

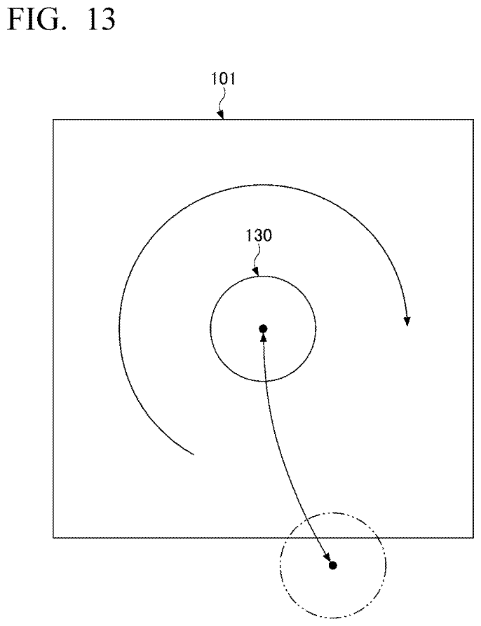

Next, an example of ultrasonic cleaning will be described with reference to FIGS. 12 and 13. The ultrasonic cleaning is performed at least at one timing selected from before and after forming the multilayer reflective film 11 (step S103) and before and after forming the absorbing film 13 (step S105). The ultrasonic cleaning is performed such that the defect D1 is not present in the vicinity of the first reference mark M1 and the defect D2 is not present in the vicinity of the second reference mark M2. The detailed description will be provided below.

As shown in FIG. 12, an ultrasonic cleaning device 100 cleans a target substrate 101 by applying ultrasonic vibrations to a liquid film F formed on the target substrate 101. Particles adhering to the target substrate 101 can be removed. The target substrate 101 includes the substrate 10. The target substrate 101 may include only the substrate 10, or may include the substrate 10 and a film (for example, the multilayer reflective film 11) formed on the substrate 10.

The ultrasonic cleaning device 100 includes a holding unit 110, a nozzle 120, a cleaning head 130, a rotating unit 140, a first moving unit 150, a second moving unit 160, and a control unit 190. The holding unit 110 holds the target substrate 101 horizontally. The nozzle 120 forms the liquid film F by supplying a cleaning liquid onto the upper surface of the target substrate 101 held by the holding unit 110. The nozzle 120 may be provided outside the cleaning head 130 as shown in FIG. 12, or may be provided inside the cleaning head 130, although it is not shown.

The cleaning liquid is, for example, pure water (for example, deionized water), a mixture of pure water and X, a mixture of pure water and Y, a mixture of pure water and Z, a mixture of pure water, X, and Z, or a mixture of pure water, Y, and Z. X is at least one component selected from the group consisting of hydrochloric acid, sulfuric acid, nitric acid, phosphoric acid, formic acid, and acetic acid. Y is at least one component selected from the group consisting of ammonia, tetramethylammonium hydroxide, triethanolamine, choline, sodium hydroxide, potassium hydroxide, and cesium hydroxide. Z is at least one component selected from the group consisting of hydrogen peroxide, perchlorate ions, and periodate ions.

The cleaning liquid may have at least one gas selected from the group consisting of H₂ gas, CO₂ gas, N₂ gas, O₂ gas, O₃ gas, and Ar gas, and the gas is dissolved in the cleaning liquid. By controlling the amount of dissolved gas, it is possible to improve the efficiency of cavitation generation and particle removal efficiency. The gas dissolved in the cleaning liquid is preferably H₂ gas, CO₂ gas or N₂ gas, and more preferably CO₂ gas.

The cleaning head 130 applies ultrasonic vibrations to the liquid film F and applies sound pressure to the target substrate 101. This allows particles adhering to the upper surface of the target substrate 101 to be peeled off. The cleaning head 130 includes a vibration plate that comes into contact with the liquid film F and an ultrasonic vibrator that vibrates the vibration plate. The lower surface of the vibration plate is smaller than the upper surface of the target substrate 101 and is disposed parallel to the upper surface of the target substrate 101.

The rotating unit 140 rotates the target substrate 101 together with the holding unit 110. The rotating unit 140 includes, for example, a motor and a transmission mechanism that transmits the rotational motion of the motor to the holding unit 110. The transmission mechanism includes, for example, a gear or a timing belt. The first moving unit 150 moves the cleaning head 130 in a horizontal direction perpendicular to the rotation center line of the holding unit 110. The first moving unit 150 moves the cleaning head 130 between a position directly above the center of the target substrate 101 and a position directly above the periphery of the target substrate 101. The first moving unit 150 has, for example, a rotating arm on which the cleaning head 130 is provided, and a motor that rotates the rotating arm. The second moving unit 160 moves the cleaning head 130 in a vertical direction to adjust the interval between the cleaning head 130 and the target substrate 101. The second moving unit 160 includes, for example, a lifter.

The control unit 190 is, for example, a computer, and includes a calculation unit 191 such as a central processing unit (CPU) and a storage unit 192 such as a memory. The storage unit 192 stores a program for controlling various processes executed in the ultrasonic cleaning device 100. The control unit 190 controls the operation of the ultrasonic cleaning device 100 by causing the calculation unit 191 to execute the program stored in the storage unit 192.

The control unit 190 includes an electronic circuit such as a CPU, a field programmable gate array (FPGA), or an application specific integrated circuit (ASIC), and executes the various control operations described in this specification by executing instruction codes stored in a memory or by being a circuit designed for a specific application.

First, the holding unit 110 holds the target substrate 101. Next, the rotating unit 140 rotates the target substrate 101 together with the holding unit 110, and the nozzle 120 supplies the cleaning liquid near the center of the target substrate 101. The cleaning liquid on the target substrate 101 spreads from the center to the periphery of the target substrate 101 due to centrifugal force. As a result, the liquid film F is formed on the entire upper surface of the target substrate 101.

In a state in which the liquid film F is formed on the entire upper surface of the target substrate 101, the cleaning head 130 applies ultrasonic vibrations to the liquid film F and applies sound pressure to the target substrate 101. This allows particles adhering to the upper surface of the target substrate 101 to be peeled off. The first moving unit 150 reciprocates the cleaning head 130 repeatedly between a position directly above the center of the target substrate 101 and a position directly above the periphery of the target substrate 101. This allows the entire upper surface of the target substrate 101 to be cleaned. In the present embodiment, the upper surface of the target substrate 101 is the surface of the multilayer reflective film 11, but it may also be the surface of the absorbing film 13 or the surface of another functional film.

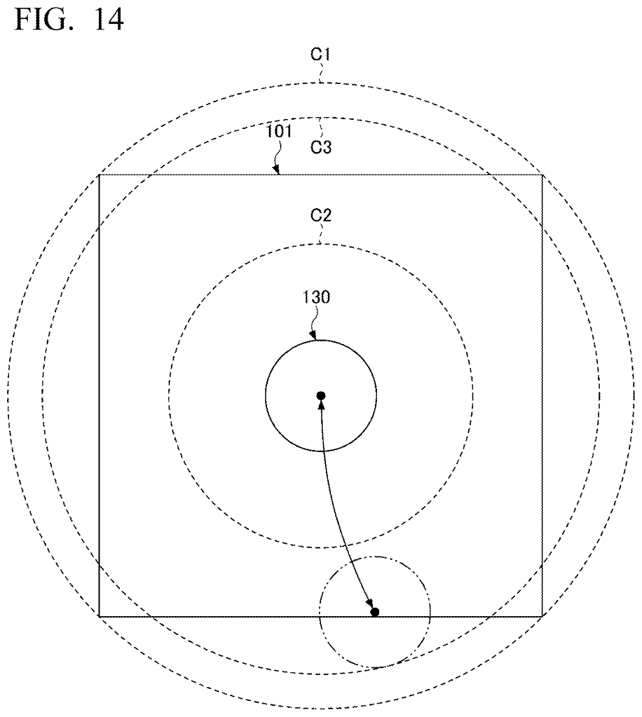

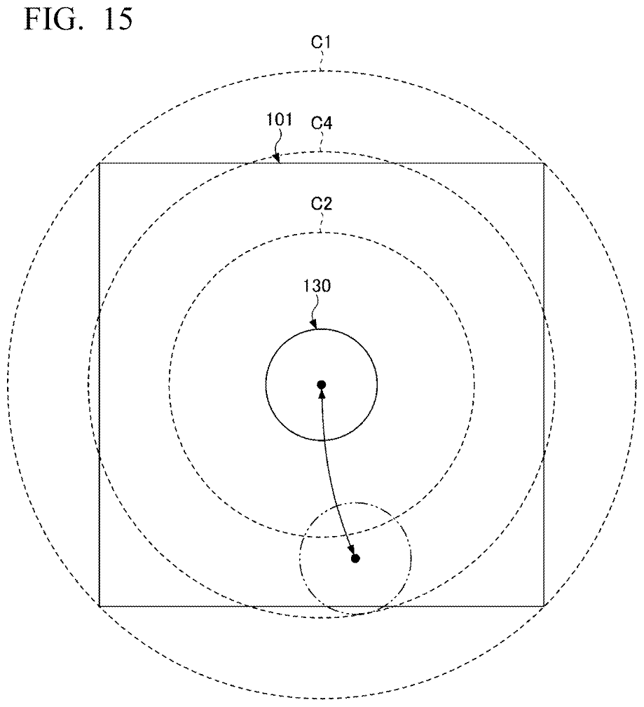

It is preferable to set the moving speed of the cleaning head 130 as follows such that the defect having approximately the same size as the reference mark (for example, the first reference mark M1 or the second reference mark M2) is not present in the vicinity of the reference mark. The moving speed of the cleaning head 130 will be described below with reference to FIGS. 14 and 15.

In FIGS. 14 and 15, C1 is a first circle and C2 is a second circle. The first circle C1 is a circumscribing circle of the upper surface of the target substrate 101 (for example, the surface of the multilayer reflective film 11). The second circle C2 is a circle that is concentric with the first circle C1 and has a diameter that is half that of the first circle C1. A third circle C3 and a fourth circle C4 will be described later.

In the following description, a first time T1 is a time during which the center of the cleaning head 130 stays inside the second circle C2, and a second time T2 is a time during which the center of the cleaning head 130 stays outside the second circle C2 and inside the first circle C1. It is preferable to set the moving speed of the cleaning head 130 such that the ratio of the second time T2 to the total time (T1+T2) of the first time T1 and the second time T2 is 65% to 90%.

If the ratio of the second time T2 to the total time (T1+T2) is 65% to 90%, the peripheral portion of the upper surface of the target substrate 101 can be thoroughly cleaned. The reference marks are provided on the peripheral portion of the upper surface of the target substrate 101. Therefore, by thoroughly cleaning the peripheral portion of the upper surface of the target substrate 101, it is possible to prevent the defect having approximately the same size as the reference mark from being present in the vicinity of the reference mark.

The ratio of the second time T2 to the total time (T1+T2) is preferably 65% to 90%, more preferably 67% to 85%, even more preferably 69% to 83%, and particularly preferably 70% to 80%.

Next, Test Example 1 and Test Example 2 will be described with reference to FIGS. 14 and 15 and Table 1. In Test Example 1 and Test Example 2, the multilayer reflective film coated substrates 3 that each have the substrate 10 and the multilayer reflective film 11 were prepared under the same conditions except for the ultrasonic cleaning conditions, and the position of the defect D1 in the multilayer reflective film 11 was inspected using a deep ultraviolet (DUV) inspection device. Test Example 1 is an example, and Test Example 2 is a comparative example.

As the substrate 10, a SiO₂—TiO₂ based glass substrate (outer size of 6 inch (152 mm) square, thickness of 6.3 mm) was prepared. This glass substrate had a linear expansion coefficient at 20° C. of 0.02×10⁻⁷/° C., a Young's modulus of 67 GPa, a Poisson's ratio of 0.17, and a specific rigidity of 3.07×10⁷ m²/s².

As the multilayer reflective film 11, a Mo/Si multilayer reflective film was formed. The Mo/Si multilayer reflective film was formed by repeating the process of depositing a Si layer (film thickness: 4.5 nm) and a Mo layer (film thickness: 2.3 nm) 40 cycles using an ion beam sputtering method. The total film thickness of the Mo/Si multilayer reflective film was 272 nm ((4.5 nm+2.3 nm)×40).

In Test Example 1, immediately before the formation of the multilayer reflective film 11, the ultrasonic cleaning was performed on the first main surface 10a of the substrate 10 while rotating the substrate 10. Pure water was used as the cleaning liquid. As shown in FIG. 14, the cleaning head 130 was reciprocated within the entire inside of the third circle C3 without going outside the third circle C3. The radius of the third circle C3 was 96 mm. Incidentally, the radius of the first circle C1 was approximately 107 mm, and the radius of the second circle C2 was approximately 54 mm. Here, the moving speed of the cleaning head 130 was set such that the ratio of the first time T1 to the second time T2 became the ratio shown in Table 1.

In addition, in Test Example 1, immediately after the formation of the multilayer reflective film 11, the ultrasonic cleaning was performed on the surface 11a of the multilayer reflective film 11 while rotating the multilayer reflective film coated substrate 3. Pure water was used as the cleaning liquid. As shown in FIG. 14, the cleaning head 130 was reciprocated within the entire inside of the third circle C3 without going outside the third circle C3. Here, the moving speed of the cleaning head 130 was set such that the ratio of the first time T1 to the second time T2 became the ratio shown in Table 1.

In Test Example 2, similarly to Test Example 1, immediately before the formation of the multilayer reflective film 11, the ultrasonic cleaning was performed on the first main surface 10a of the substrate 10 while rotating the substrate 10. However, as shown in FIG. 15, the cleaning head 130 was reciprocated within the entire inside of the fourth circle C4 without going outside the fourth circle C4. The radius of the fourth circle C4 was 80 mm. Incidentally, the radius of the first circle C1 was approximately 107 mm, and the radius of the second circle C2 was approximately 54 mm. Here, the moving speed of the cleaning head 130 was set such that the ratio of the first time T1 to the second time T2 became the ratio shown in Table 1. In Test Example 1 and Test Example 2, the movement range of the cleaning head 130 and the ratio of the first time T1 to the second time T2 were changed, but the cleaning time was set to the same.

In addition, in Test Example 2, similarly to Test Example 1, immediately after the formation of the multilayer reflective film 11, the ultrasonic cleaning was performed on the surface 11a of the multilayer reflective film 11 while rotating the multilayer reflective film coated substrate 3. However, as shown in FIG. 15, the cleaning head 130 was reciprocated within the entire inside of the fourth circle C4 without going outside the fourth circle C4. Here, the moving speed of the cleaning head 130 was set such that the ratio of the first time T1 to the second time T2 became the ratio shown in Table 1. In Test Example 1 and Test Example 2, the movement range of the cleaning head 130 and the ratio of the first time T1 to the second time T2 were changed, but the cleaning time was set to the same.

TABLE 1

| | Example 1 | Example 2 |
|---|---|---|
| Ti [%] | 25 | 36 |
| T2 [%] | 75 | 64 |
| Presence or absence | Absence | Presence |
| of defect | | |

Table 1 shows the ratio of the first time T1 to the second time T2, and the presence or absence of the defect D1 having approximately the same size as the first reference mark M1 within 1000 μm from the first reference mark M1. The first reference mark M1 was a square. As the circle equivalent diameter of the defect D1 having approximately the same size as the first reference mark M1, 50% to 150% of the circle equivalent diameter of the first reference mark M1 was employed. That is, as the circle equivalent diameter of the defect D1 having approximately the same size as the first reference mark M1, 56% to 169% of the average value of the lengths of the respective sides of the first reference mark M1 was employed.

In Test Example 1, compared to Test Example 2, the movement range of the cleaning head 130 was increased by 1.2 times toward the radially outer side of the target substrate 101, and the proportion of the first time T1 was reduced and the proportion of the second time T2 was increased. As a result, in Test Example 1, unlike Test Example 2, the defect D1 having approximately the same size as the first reference mark M1 was not present within 1000 μm of the first reference mark M1.

In the above, the multilayer reflective film coated substrate, the reflective mask blank, the reflective mask, the method for manufacturing a multilayer reflective film coated substrate, the method for manufacturing a reflective mask blank, and the method for manufacturing a reflective mask according to the present disclosure have been described, but the present disclosure is not limited to the above-described embodiments. Various changes, modifications, substitutions, additions, deletions, and combinations are possible within the scope of the claims. Naturally, these also fall within the technical scope of the present disclosure.

### BRIEF DESCRIPTION OF THE REFERENCE SYMBOLS

1 Reflective mask blank
2 Reflective mask
3 Multilayer reflective film coated substrate
10 Substrate
11 Multilayer reflective film
13 Absorbing film
M1 First reference mark
D1 Defect

1. A multilayer reflective film coated substrate comprising: a substrate; and a multilayer reflective film that reflects EUV light,
wherein the multilayer reflective film has, on a peripheral portion of a surface thereof on a side opposite to the substrate, three or more first reference marks to be used as reference positions when a position of a defect in the multilayer reflective film is identified, and
wherein a defect having approximately the same size as each of the three or more first reference marks is not present within 100 μm from the first reference mark in the multilayer reflective film when the surface of the multilayer reflective film is viewed from a front surface.

2. The multilayer reflective film coated substrate according to claim 1, wherein a circle equivalent diameter of the defect having approximately the same size as the first reference mark is 80% to 120% of a circle equivalent diameter of the first reference mark.

3. The multilayer reflective film coated substrate according to claim 1,
wherein each of the three or more first reference marks is rectangular when the surface of the multilayer reflective film is viewed from a front surface, and
wherein a circle equivalent diameter of the defect having approximately the same size as the first reference mark is 90% to 135% of an average value of lengths of respective sides of the first reference mark.

4. A reflective mask blank comprising: a substrate; a multilayer reflective film that reflects EUV light; and an absorbing film that absorbs EUV light, in that order,
wherein the multilayer reflective film has, on a peripheral portion of a surface thereof on a side opposite to the substrate, three or more first reference marks to be used as reference positions when a position of a defect in the multilayer reflective film is identified,
wherein a defect having approximately the same size as each of the three or more first reference marks is not present within 100 μm from the first reference mark in the multilayer reflective film when the surface of the multilayer reflective film is viewed from a front surface,
wherein the absorbing film has, on a peripheral portion of a surface thereof on a side opposite to the multilayer reflective film, three or more second reference marks to be used as reference positions when a position of a defect in the absorbing film is identified,
wherein the second reference marks are transferred from the first reference marks, and
wherein a defect having approximately the same size as each of the three or more second reference marks is not present within 100 μm from the second reference mark in the absorbing film when the surface of the absorbing film is viewed from a front surface.

5. The reflective mask blank according to claim 4,
wherein a circle equivalent diameter of the defect having approximately the same size as the first reference mark is 80% to 120% of a circle equivalent diameter of the first reference mark, and
wherein a circle equivalent diameter of the defect having approximately the same size as the second reference mark is 80% to 120% of a circle equivalent diameter of the second reference mark.

6. The reflective mask blank according to claim 4,
wherein each of the three or more first reference marks is rectangular when the surface of the multilayer reflective film is viewed from a front surface,
wherein a circle equivalent diameter of the defect having approximately the same size as the first reference mark is 90% to 135% of an average value of lengths of respective sides of the first reference mark,
wherein each of the three or more second reference marks is rectangular when the surface of the absorbing film is viewed from a front surface, and
wherein a circle equivalent diameter of the defect having approximately the same size as the second reference mark is 90% to 135% of an average value of lengths of respective sides of the second reference mark.

7. A reflective mask comprising the reflective mask blank according to claim 4,
wherein an opening pattern is included in the absorbing film.

8. A reflective mask comprising the reflective mask blank according to claim 5,
wherein an opening pattern is included in the absorbing film.

9. A reflective mask comprising the reflective mask blank according to claim 6,
wherein an opening pattern is included in the absorbing film.

10. A method for manufacturing a multilayer reflective film coated substrate, comprising: forming, on a substrate, a multilayer reflective film that reflects EUV light; and identifying a position of a defect in the multilayer reflective film,
wherein the multilayer reflective film has, on a peripheral portion of a surface thereof on a side opposite to the substrate, three or more first reference marks to be used as reference positions when the position of the defect in the multilayer reflective film is identified, and
wherein a defect having approximately the same size as each of the three or more first reference marks is not present within 100 μm from the first reference mark in the multilayer reflective film when the surface of the multilayer reflective film is viewed from a front surface.

11. The method for manufacturing a multilayer reflective film coated substrate according to claim 10,
wherein, immediately after forming the multilayer reflective film, the surface of the multilayer reflective film is subjected to ultrasonic cleaning,
wherein a cleaning head is used during the ultrasonic cleaning, and
wherein, when a circumscribing circle of the surface of the multilayer reflective film is defined as a first circle, a circle that is concentric with the first circle and has a diameter that is half that of the first circle is defined as a second circle, a time during which a center of the cleaning head stays inside the second circle is defined as a first time, and a time during which the center of the cleaning head stays outside the second circle and inside the first circle is defined as a second time,
a moving speed of the cleaning head is controlled such that a ratio of the second time (T2) to the total time (T1+T2) of the first time (T1) and the second time (T2) is 65% to 90%.

12. A method for manufacturing a reflective mask blank, comprising: forming, on a substrate, a multilayer reflective film that reflects EUV light and an absorbing film that absorbs EUV light, in that order; identifying a position of a defect in the multilayer reflective film; and identifying a position of a defect in the absorbing film,
wherein the multilayer reflective film has, on a peripheral portion of a surface thereof on a side opposite to the substrate, three or more first reference marks to be used as reference positions when the position of the defect in the multilayer reflective film is identified,
wherein a defect having approximately the same size as each of the three or more first reference marks is not present within 100 μm from the first reference mark in the multilayer reflective film when the surface of the multilayer reflective film is viewed from a front surface,
wherein the absorbing film has, on a peripheral portion of a surface thereof on a side opposite to the multilayer reflective film, three or more second reference marks to be used as reference positions when a position of a defect in the absorbing film is identified,
wherein the second reference marks are transferred from the first reference marks, and
wherein a defect having approximately the same size as each of the three or more second reference marks is not present within 100 μm from the second reference mark in the absorbing film when the surface of the absorbing film is viewed from a front surface.

13. The method for manufacturing a reflective mask blank according to claim 12,
wherein, immediately after forming the multilayer reflective film, the surface of the multilayer reflective film is subjected to ultrasonic cleaning,
wherein a cleaning head is used during the ultrasonic cleaning, and
wherein, when a circumscribing circle of the surface of the multilayer reflective film is defined as a first circle, a circle that is concentric with the first circle and has a diameter that is half that of the first circle is defined as a second circle, a time during which a center of the cleaning head stays inside the second circle is defined as a first time, and a time during which the center of the cleaning head stays outside the second circle and inside the first circle is defined as a second time,
a moving speed of the cleaning head is controlled such that a ratio of the second time (T2) to the total time (T1+T2) of the first time (T1) and the second time (T2) is 65% to 90%.

14. A method for manufacturing a reflective mask, comprising:
preparing the reflective mask blank according to claim 4; and
forming an opening pattern in the absorbing film,
in that order.

15. A method for manufacturing a reflective mask, comprising:
preparing the reflective mask blank according to claim 5; and
forming an opening pattern in the absorbing film,
in that order.

16. A method for manufacturing a reflective mask, comprising:
preparing the reflective mask blank according to claim 6; and
forming an opening pattern in the absorbing film,
in that order.
